(19) United States
(12) Patent Application Publication
(10) Pub. No.: US 2020/0163228 A1
(43) Pub. Date: May 21, 2020

(54) PRINTED CIRCUIT BOARD

(71) Applicant: Samsung Electro-Mechanics Co., Ltd., Suwon-si (KR)

(72) Inventors: Sa-Yong LEE, Suwon-si (KR); Tae-Hong MIN, Suwon-si (KR)

(73) Assignee: Samsung Electro-Mechanics Co., Ltd., Suwon-si (KR)

(21) Appl. No.: 16/664,113

(22) Filed: Oct. 25, 2019

(30) Foreign Application Priority Data
Nov. 15, 2018 (KR) 10-2018-0141025

(51) Int. Cl. H05K 3/36; H05K 1/18; H01L 23/498

(52) U.S. Cl. CPC H05K 3/361; H01L 23/4985; H05K 1/188

(57) ABSTRACT

A printed circuit board includes: an insulating material; a metal layer disposed on a first surface of the insulating material and including an opening; a pad disposed along a second surface of the insulating material; a via hole penetrating through the insulating material and extending from the pad to the opening; and a conductor disposed along the opening and the via hole. A diameter of a portion of the via hole adjacent to the opening is smaller than a diameter of a portion of the opening adjacent to the via hole.

### CROSS-REFERENCE TO RELATED APPLICATION

This application claims the benefit under 35 USC 119(a) of Korean Patent Application No. 10-2018-0141025, filed on Nov. 15, 2018, entitled “PRINTED CIRCUIT BOARD”, the entire disclosure of which is hereby incorporated by reference for all purposes.

### BACKGROUND

### 1. Technical Field

The following description relates to a printed circuit board.

### 2. Description of the Background

Various structures of a printed circuit board have been derived in order to utilize a constrained space inside a portable device. Among these structures, for reduction of a signal loss, a structure in which an insulation thickness of the printed circuit board with respect to an open region of a via is increased has been proposed. In this case, a via void may easily occur.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a printed circuit board includes: an insulating material; a metal layer disposed on a first surface of the insulating material and including an opening; a pad disposed along a second surface of the insulating material; a via hole penetrating through the insulating material and extending from the pad to the opening; and a conductor disposed along the opening and the via hole. A diameter of a portion of the via hole adjacent to the opening is smaller than a diameter of a portion of the opening adjacent to the via hole.

The diameter of the portion of the via hole adjacent to the opening may be smaller than a diameter of a portion of the opening opposite the portion of the opening adjacent to the via hole.

The conductor may include: a seed layer continuously disposed along an inner surface of the opening and an inner surface of the via hole; and an electroplating layer disposed on the seed layer.

The seed layer may extend along a surface of the metal layer.

The electroplating layer may extend through the opening and on the metal layer.

The electroplating layer may include: a first electroplating layer disposed inside the via hole; a second electroplating layer disposed inside the opening; and a third electroplating layer disposed on the metal layer and the second electroplating layer. A width of the third electroplating layer may be greater than a width of the second electroplating layer.

A ratio of a depth of the via hole to the diameter of the portion of the opening adjacent to the via hole may be greater than 0.66 and less than 0.83.

The insulating material may include: a first resin layer; and a second resin layer stacked on the first resin layer, and the second resin layer may include a material different from a material of the first resin layer.

The first resin layer may include a thermosetting resin, and the second resin layer may include a thermoplastic resin.

A ratio of a diameter of a portion of the via hole adjacent to the pad to the diameter of the portion of the via hole adjacent to the opening may be greater than 0.8 and less than 1.

A thickness of the metal layer may be greater than a thickness of the seed layer.

In another general aspect, a printed circuit board includes: an insulating material; a first pad disposed along a first surface of the insulating material; a via penetrating through the insulating material and disposed on the first pad; and a second pad disposed on the via. The second pad includes: a metal layer having a ring shape and disposed on a second surface of the insulating material so as not to overlap the via; a seed layer continuously disposed along the second surface of the insulating material, an inner surface of the metal layer, and a surface of the metal layer; and an electroplating layer disposed on the seed layer.

An inner diameter of the metal layer may be greater than a diameter of a portion of the via adjacent to the metal layer.

A ratio of a thickness of the via to an inner diameter of the metal layer may be greater than 0.66 and less than 0.83.

The insulating material may include: a first resin layer; and a second resin layer stacked on the first resin layer, and the second resin layer may include a material different from a material of the first resin layer.

The first resin layer may include a thermosetting resin, and the second resin layer may include a thermoplastic resin.

In another general aspect, a printed circuit board includes: an insulating material; a pad disposed in the insulating material along a first surface of the insulating material; a metal layer disposed on a second surface of the insulating material and including an opening that at least partially overlaps the pad in a thickness direction of the printed circuit board; a via hole connecting the pad to the opening; and a conductor disposed in the via hole.

The opening may completely overlap the pad in the thickness direction of the printed circuit board.

The conductor may include a seed layer having a stepwise structure extending from the metal layer to the pad.

Other features and aspects will be apparent from the following detailed description, the drawings, and the claims.

### BRIEF DESCRIPTION OF THE DRAWINGS

FIG. 1 illustrates a printed circuit board according to an example.

FIG. 2 illustrates a printed circuit board according to an example.

FIG. 3 illustrates a printed circuit board according to an example.

FIG. 4 illustrates a printed circuit board according to an example.

FIGS. 5(a), 5(b), 5(c), 5(d), 5(e), and 5(f) illustrate a method for manufacturing a printed circuit board according to an example.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known in the art may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Herein, it is noted that use of the term “may” with respect to an example or embodiment, e.g., as to what an example or embodiment may include or implement, means that at least one example or embodiment exists in which such a feature is included or implemented while all examples and embodiments are not limited thereto.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms such as “above,” “upper,” “below,” and “lower” may be used herein for ease of description to describe one element's relationship to another element as shown in the figures. Such spatially relative terms are intended to encompass different orientations of the device in use or operation in addition to the orientation depicted in the figures. For example, if the device in the figures is turned over, an element described as being “above” or “upper” relative to another element will then be “below” or “lower” relative to the other element. Thus, the term “above” encompasses both the above and below orientations depending on the spatial orientation of the device. The device may also be oriented in other ways (for example, rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes shown in the drawings may occur. Thus, the examples described herein are not limited to the specific shapes shown in the drawings, but include changes in shape that occur during manufacturing.

The features of the examples described herein may be combined in various ways as will be apparent after an understanding of the disclosure of this application. Further, although the examples described herein have a variety of configurations, other configurations are possible as will be apparent after an understanding of the disclosure of this application.

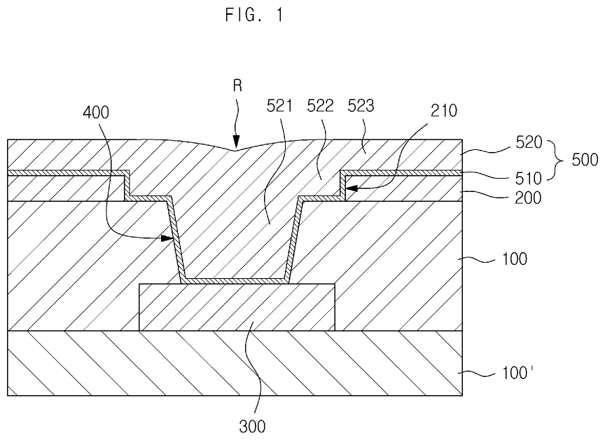

FIG. 1 illustrates a printed circuit board according to an example.

Referring to FIG. 1, a printed circuit board includes an insulating material 100, a metal layer 200, a pad 300, a via hole 400, and a conductor 500.

The insulating material 100 insulates circuits on the printed circuit board from each other. The insulating material 100 may be formed of a resin, and the resin may be various resins such as a thermoplastic resin, a thermosetting resin, a photosensitive resin, and the like. The resin of the insulating material 100 may be an epoxy resin, a polyimide (PI) resin, a bismaleimide-triazine (BT) resin, a liquid-crystal polymer (LCP) resin, a fluorine-containing resin such as a polytetrafluoroethylene resin, a polyphenylene sulfide (PPS) resin, a polyphenylene ether (PPE) resin, and the like.

A dielectric dissipation factor (Df) of the insulating material 100 may be 0.003 or less, and a dielectric constant (Dk) of the insulating material 100 may be 3.5 or less. The dielectric dissipation factor is a value corresponding to a dielectric loss and the dielectric loss is a loss power generated when an alternating electric field is formed in the insulating material 100 (dielectric). The dielectric dissipation factor is in proportion to the dielectric loss. The smaller the dielectric dissipation factor is, the smaller the dielectric loss is. A signal loss in transferring a high frequency signal may be reduced by the insulating material 100 having a low dielectric loss characteristic.

The insulating material 100 may contain a reinforcement material. The reinforcement material may be a glass fiber or an inorganic filler. The insulating material 100 containing a glass fiber is an insulating material in which a glass fiber is impregnated with a resin, and may be a prepreg (PPG). As the inorganic filler contained in the insulating material 100, an oxidized metal-based ceramic filler having a spherical shape, an acicular shape, an amorphous shape, or the like may be used. As the inorganic filler, one or more materials selected from the group consisting of silica (SiO2), alumina (Al2O3), silicon carbide (SiC), barium sulfate (BaSO4), talc, clay, mica powders, aluminum hydroxide (AlOH3), magnesium hydroxide (Mg(OH)2), calcium carbonate (CaCO3), magnesium carbonate (MgCO3), magnesium oxide (MgO), boron nitride (BN), aluminum borate (AlBO3), barium titanate (BaTiO3), and calcium zirconate (CaZrO3) may be used. A value of the dielectric dissipation factor of the insulating material 100 may be adjusted depending on a type or a content of the inorganic filler contained in the insulating material 100.

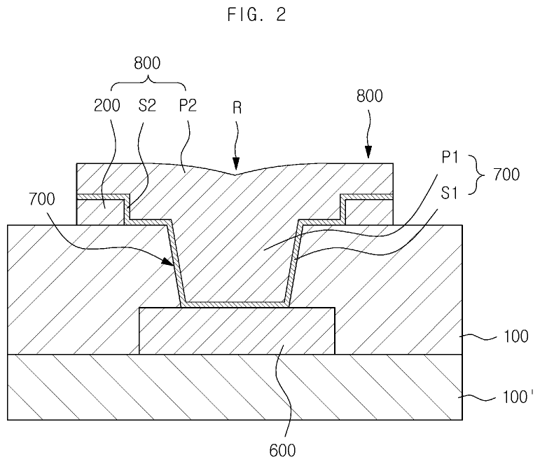

An insulating layer 100′ positioned under the insulating material 100 is illustrated in FIG. 1. The insulating layer 100′ may be the same layer as the insulating material 100. Alternatively, the insulating layer 100′ may be a layer formed of a material different from that of the insulating material 100, and may be a core layer or a solder resist layer. Such an insulating layer 100′ is illustrated in FIGS. 2 to 5F and may be omitted, if necessary.

The metal layer 200 is formed on an upper surface of the insulating material 100. The metal layer 200 may be formed of copper (Cu), silver (Ag), palladium (Pd), aluminum (Al), nickel (Ni), titanium (Ti), gold (Au), platinum (Pt), or the like.

A thickness of the metal layer 200 may be 0.2 to 5 μm.

The metal layer 200 may include an opening 210. The opening 210 may be formed by partially removing the metal layer 200 after the metal layer 200 is formed on the entire upper surface of the insulating material 100.

The opening 210 may be formed by etching or laser machining. In a case in which the opening 210 is formed by etching, a dry film resist (DFR) is formed on the metal layer 200, and then the dry film resist is patterned corresponding to a region in which the opening 210 is formed, and a portion of the metal layer 200 exposed to the dry film resist is etched by an etching solution. Skiving technique may be used for a laser machining to form the opening 210.

The opening 210 may have an upper surface and a lower surface. The upper surface of the opening 210 is coplanar with an upper surface of the metal layer 200. The lower surface of the opening 210 is coplanar with the upper surface of the insulating material 100.

A horizontal cross-sectional area of the opening 210 may be increased or decreased toward a lower portion thereof and may be vertically constant. A horizontal cross section of the opening 210 may be circular, but is not limited thereto.

The pad 300 is a conductor formed in a lower surface of the insulating material 100 and may be formed of a metal. The pad 300 may be formed of copper (Cu), silver (Ag), palladium (Pd), aluminum (Al), nickel (Ni), titanium (Ti), gold (Au), platinum (Pt), or the like.

The pad 300 may be embedded in the lower surface of the insulating material 100. In this case, surfaces of the pad 300 other than a lower surface of the pad 300 may be in contact with the insulating material 100. The pad 300 is completely embedded in the insulating material 100, such that all the surfaces of the pad 300 except for the lower surface of the pad 300 may be in contact with the insulating material 100.

The pad 300 may include a metal layer and a seed layer.

The via hole 400 is a hole penetrating through the insulating material 100, positioned on the pad 300, and connected to the opening 210. That is, the via hole 400 may be formed to have a thickness from the upper surface of the insulating material 100 to an upper surface of the pad 300. The via hole 400 may be formed by a laser machining. A CO2 laser, an UV laser, or the like may be used for the laser machining.

The via hole 400 has an upper surface and a lower surface. The upper surface of the via hole 400 is coplanar with the upper surface of the insulating material 100. The lower surface of the via hole 400 is coplanar with the upper surface of the pad 300.

The upper surface of the via hole 400 may be greater than the lower surface of the via hole 400. In this case, a horizontal cross-sectional area of the via hole 400 may be decreased from the upper surface of the insulating material 100 toward a lower portion of the insulating material 100. That is, a longitudinal section of the via hole 400 may have a reversed trapezoidal shape. In this case, a ratio of the area of the lower surface of the via hole 400 to the area of the upper surface of the via hole 400 may be 0.8 or more.

A horizontal cross section of the via hole 400 may be circular, but is not limited thereto.

The upper surface of the via hole 400 may be overlapped with the lower surface of the opening 210. The upper surface of the via hole 400 may be included in the lower surface of the opening 210. In this case, the center of the upper surface of the via hole 400 may coincide with the center of the lower surface of the opening 210. In addition, a diameter of the upper surface of the via hole 400 is smaller than a diameter of the lower surface of the opening 210. The diameter of the upper surface of the via hole 400 may be smaller than a diameter of the upper surface of the opening 210. The horizontal cross-sectional area of the opening 210 may be constant in a vertical direction of the opening 210.

A ratio of a depth of the via hole 400 to the diameter of the lower surface of the opening 210 may be greater than 0.66 and smaller than 0.83. When the ratio of a depth of the via hole 400 to the diameter of the lower surface of the opening 210 is 0.66 or smaller or greater than 0.83, a void and/or a dimple defect may occur in the conductor 500.

The term “depth of the via hole 400” is a distance from an upper surface of the insulating material 100 to the upper surface of the pad 300, which is referred to as an “insulating distance”.

The conductor 500 is a conductive member, which is formed inside the opening 210 and inside the via hole 400, and may be formed of a metal such as copper (Cu), silver (Ag), palladium (Pd), aluminum (Al), nickel (Ni), titanium (Ti), gold (Au), platinum (Pt), or the like.

The conductor 500 may include a seed layer 510 and an electroplating layer 520.

The seed layer 510 is continuously formed on an inner surface of the opening 210, the lower surface of the opening 210 (the upper surface of the insulating material 100), an inner surface of the via hole 400, and the lower surface of the via hole 400 (the upper surface of the pad 300) and may be an electroless plating layer formed by an electroless plating method. The seed layer 510 may be formed of a metal such as copper (Cu), silver (Ag), palladium (Pd), aluminum (Al), nickel (Ni), titanium (Ti), gold (Au), platinum (Pt), or the like. The metal of the seed layer 510 may be the same metal as the metal layer 200.

A thickness of the seed layer 510 may be 0.01 to 1.5 μm. The thickness of the seed layer 510 may be smaller than the thickness of the metal layer 200.

The seed layer 510 may extend on the upper surface of the metal layer 200. That is, the seed layer 510 may be continuously formed on the lower surface of the via hole 400, the inner surface of the via hole 400, the lower surface of the opening 210 (that is, the upper surface of the insulating material 100), the inner surface of the opening 210, and the upper surface of the metal layer 200.

The electroplating layer 520 is formed on the seed layer 510 to be in contact with the seed layer 510. The electroplating layer 520 is formed inside the opening 210 and inside the via hole 400. The electroplating layer 520 may be formed by an electroplating method and may be formed of a metal such as copper (Cu), silver (Ag), palladium (Pd), aluminum (Al), nickel (Ni), titanium (Ti), gold (Au), platinum (Pt), or the like.

The electroplating layer 520 may further be formed on the opening 210 and may extend above the metal layer 200.

The electroplating layer 520 may be divided into a first electroplating layer 521, a second electroplating layer 522, and a third electroplating layer 523. The first electroplating layer 521 is positioned in the via hole 400, the second electroplating layer 522 is positioned in the opening 210, and the third electroplating layer 523 is positioned on the upper surface of the metal layer 200 and an upper surface of the second electroplating layer 522. A width of the third electroplating layer 523 is greater than a width of the second electroplating layer 522. The first electroplating layer 521, the second electroplating layer 522, and the third electroplating layer 523 are integrally formed.

An upper surface of the electroplating layer 520 may include a recess R. However, the recess R is not regarded as a dimple defect. The recess R may be removed by polishing or the like.

FIG. 2 illustrates a printed circuit board according to another example.

Referring to FIG. 2, a printed circuit board includes an insulating material 100, a first pad 600, a via 700, and a second pad 800.

The insulating material 100 is the same as the insulating material 100 described with respect to FIG. 1. The first pad 600 is formed on a lower surface of the insulating material 100, in a similar manner as the pad 300 described with respect to FIG. 1.

The via 700 penetrates through the insulating material 100 and is formed on the first pad 600. The via 700 may be formed by filling the via hole 400 with a conductive material, the via hole 400 penetrating through the insulating material 100 and being positioned on the first pad 600. A horizontal cross section of the via 700 may be circular.

The via 700 includes a first seed layer S1 and an electroplating layer P1. The conductive material forming the via 700 includes the first seed layer S1 and the electroplating layer P1.

The first seed layer S1 is formed on an inner surface and a lower surface of the via hole 400 and is in contact with the insulating material 100 and the first pad 600. The first seed layer S1 may be an electroless plating layer. The first seed layer S1 may be formed of a metal such as copper (Cu), silver (Ag), palladium (Pd), aluminum (Al), nickel (Ni), titanium (Ti), gold (Au), platinum (Pt), or the like. The electroplating layer P1 occupies the majority of the via 700. The electroplating layer P1 is formed on the first seed layer S1 and fills the via hole 400.

The second pad 800 is formed on the via hole 700 and includes a metal layer 200, a second seed layer S2, and an electroplating layer P2.

The metal layer 200 has a ring shape, does not cover the via 700, and is formed to protrude from the upper surface of the insulating material 100. The metal layer 200 may be completely spaced apart from an upper surface of the via 700 and may not be overlapped with the via 700 at all. That is, an inner diameter of the ring-shaped metal layer 200 is greater than a diameter of the upper surface of the via 700. The metal layer 200 may have a circular or polygonal ring shape.

The second seed layer S2 is connected to and integrally formed with the first seed layer S1, and is exposed to a side surface of the second pad 800. The second seed layer S2 may be formed of a metal such as copper (Cu), silver (Ag), palladium (Pd), aluminum (Al), nickel (Ni), titanium (Ti), gold (Au), platinum (Pt), or the like.

The second seed layer S2 is continuously formed on the upper surface of the insulating material 100, an inner surface of the metal layer 200, and the upper surface of the metal layer 200. Such a second seed layer S2 has a stepwise structure in the second pad 800. That is, the second seed layer S2 may have an upward stepwise structure from the upper surface of the insulating material 100 to the upper surface of the metal layer 200.

The electroplating layer P2 occupies the majority of the second pad 800 and is formed on the second seed layer S2. The electroplating layer P2 in the second pad 800 is formed integrally with the electroplating layer P1 in the via 700. An upper surface of the electroplating layer P2 in the second pad 800 may be provided with a recess R. However, the recess R is distinguished from the dimple defect due to a lower depth of the recess R than that in the case of the dimple defect.

A ratio of a depth of via hole 400 to the inner diameter of the ring-shaped metal layer 200 may be greater than 0.66 and smaller than 0.83. A void in the via 700 and/or a dimple defect in the second pad 800 may occur when a ratio of the depth of via hole 400 to the inner diameter of the ring-shaped metal layer 200 is 0.66 or smaller or greater than 0.83.

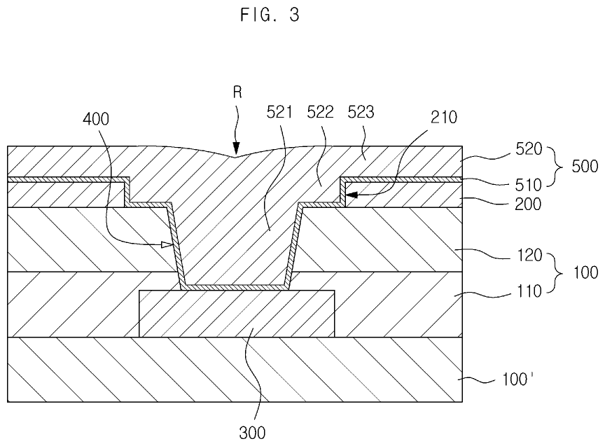

FIG. 3 illustrates a printed circuit board according to another example.

Referring to FIG. 3, the printed circuit board includes an insulating material 100, a metal layer 200, a pad 300, a via hole 400, and a conductor 500. The insulating material 100 in FIG. 3 is different from the insulating material 100 in FIG. 1 in that the insulating material 100 in FIG. 1 is formed of a single layer, whereas the insulating material 100 in FIG. 3 includes a first resin layer 110 and a second resin layer 120. Only such a difference will be described and an overlapped description of the same components will be omitted.

The first resin layer 110 is positioned adjacent to the pad 300 and the second resin layer 120 is positioned on the first resin layer 110. The first resin layer 110 may serve as a bonding sheet. A thickness of the first resin layer 110 may be smaller than a thickness of the second resin layer 120.

The second resin layer 120 may be formed of a material different from that of the first resin layer 110. The first resin layer 110 may be formed of a thermosetting resin and the second resin layer 120 may be formed of a thermoplastic resin.

The resin of the first resin layer 110 may be a polyphenylene ether (PPE) resin, a polyphenylene oxide resin, an epoxy resin, a polyvinyl resin, and the like. The resin of the second resin layer 120 may be an epoxy resin, a polyimide (PI) resin, a bismaleimide-triazine (BT) resin, a liquid-crystal polymer (LCP) resin, a fluorine-containing resin such as a polytetrafluoroethylene resin, a polyphenylene sulfide (PPS) resin, a polyphenylene ether (PPE) resin, and the like.

Dielectric dissipation factors (Df) of the first resin layer 110 and the second resin layer 120 may be 0.003 or less and dielectric constants (Dk) of the first resin layer 110 and the second resin layer 120 may be 3.5 or less.

The first resin layer 110 and the second resin layer 120 each may contain an inorganic filler. As the inorganic filler, an oxidized metal-based ceramic filler having a spherical shape, an acicular shape, an amorphous shape, or the like may be used. In detail, as the inorganic filler, one or more materials selected from the group consisting of silica (SiO2), alumina (Al2O3), silicon carbide (SiC), barium sulfate (BaSO4), talc, clay, mica powders, aluminum hydroxide (AlOH3), magnesium hydroxide (Mg(OH)2), calcium carbonate (CaCO3), magnesium carbonate (MgCO3), magnesium oxide (MgO), boron nitride (BN), aluminum borate (AlBO3), barium titanate (BaTiO3), and calcium zirconate (CaZrO3) may be used. A value of the dielectric dissipation factor may be adjusted depending on a type or a content of the inorganic filler contained in the insulating material 100.

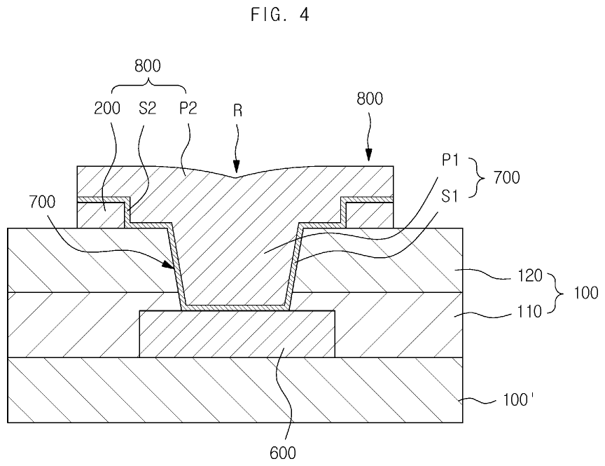

FIG. 4 illustrates a printed circuit board according to another example.

Referring to FIG. 4, the printed circuit board includes an insulating material 100, a first pad 600, a via 700, and a second pad 800.

The printed circuit board with reference to FIG. 4 includes the insulating material 100, the first pad 600, the via 700, and the second pad 800. The printed circuit board with reference to FIG. 4 is different from the printed circuit board with reference to FIG. 2 in that the insulating material 100 with reference to FIG. 4 includes a first resin layer 110 and a second resin layer 120. The first resin layer 110 and the second resin layer 120 are the same as those described with reference to FIG. 3.

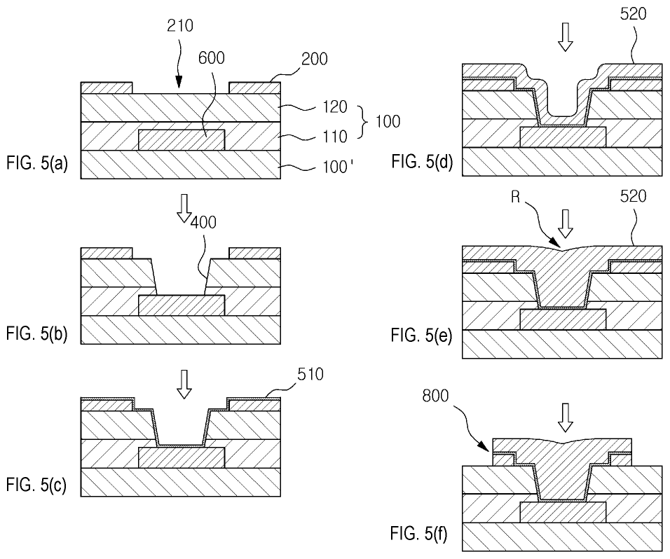

FIGS. 5(a) to 5(f) illustrate a method for manufacturing a printed circuit board according to an example. Hereinafter, a method for manufacturing a printed circuit board will be described.

Referring to FIG. 5(a), a first pad 600 is formed on an insulating layer 100′, an insulating material 100 including a second resin layer 120 stacked on a first resin layer 110 is formed on the insulating layer 100′, and a metal layer 200 is formed on the second resin layer 120. Here, the insulating material may be the same resin layer as the second resin layer 120, but is not limited thereto. Meanwhile, in the manufacture of the printed circuit board, raw materials in which the first resin layer 110, the second resin layer 120, and the metal layer 200 are stacked in advance may be used.

In the metal layer 200, an opening 210 is formed by etching or a laser machining. When the opening 210 is machined, the second resin layer 120 is not machined.

Referring to FIG. 5(b), a via hole 400 is formed in the first resin layer 110 and the second resin layer 120. An upper surface of the via hole 400 may be formed to be smaller than a lower surface of the opening 210. That is, the via hole 400 is formed inside the opening 210.

Referring to FIG. 5(c), a seed layer 510 is continuously formed on a lower surface of the via hole 400, an inner surface of the via hole 400, an upper surface of the second resin layer 120, an inner surface of the opening 210, and an upper surface of the metal layer 200. That is, the seed layer 510 has a stepwise structure.

Referring to FIG. 5(d), an electroplating layer 520 is formed on the seed layer 510. The electroplating layer 520 may be grown isotropically from the seed layer 510. Since the opening 210 is formed to be wider than the via hole 400, occurrences of a void in the electroplating layer 520 and a dimple defect in an upper surface of the electroplating layer 520 may be reduced.

Referring to FIG. 5(e), the electroplating layer 520 is formed at a predetermined height. A recess R is formed on the upper surface of the electroplating layer 520, and the recess R may be removed by polishing the electroplating layer 520, if necessary.

Referring to FIG. 5(f), a second pad 800 is formed by patterning the metal layer 200, the seed layer 510, and the electroplating layer 520. The seed layer 510 may be exposed to a side surface of the second pad 800. In addition, a circuit (not illustrated) may be formed together by patterning the metal layer 200, the seed layer 510, and the electroplating layer 520, if necessary.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A printed circuit board comprising:
an insulating material;
a metal layer disposed on a first surface of the insulating material and comprising an opening;
a pad disposed along a second surface of the insulating material;
a via hole penetrating through the insulating material and extending from the pad to the opening; and
a conductor disposed along the opening and the via hole,
wherein a diameter of a portion of the via hole adjacent to the opening is smaller than a diameter of a portion of the opening adjacent to the via hole.

2. The printed circuit board of claim 1, wherein the diameter of the portion of the via hole adjacent to the opening is smaller than a diameter of a portion of the opening opposite the portion of the opening adjacent to the via hole.

3. The printed circuit board of claim 1, wherein the conductor comprises:
a seed layer continuously disposed along an inner surface of the opening and an inner surface of the via hole; and
an electroplating layer disposed on the seed layer.

4. The printed circuit board of claim 3, wherein the seed layer extends along a surface of the metal layer.

5. The printed circuit board of claim 4, wherein the electroplating layer extends through the opening and on the metal layer.

6. The printed circuit board of claim 5, wherein the electroplating layer comprises:
a first electroplating layer disposed inside the via hole;
a second electroplating layer disposed inside the opening; and
a third electroplating layer disposed on the metal layer and the second electroplating layer, wherein
a width of the third electroplating layer is greater than a width of the second electroplating layer.

7. The printed circuit board of claim 1, wherein a ratio of a depth of the via hole to the diameter of the portion of the opening adjacent to the via hole is greater than 0.66 and less than 0.83.

8. The printed circuit board of claim 1, wherein the insulating material comprises:
a first resin layer; and
a second resin layer stacked on the first resin layer, and comprising a material different from a material of the first resin layer.

9. The printed circuit board of claim 8, wherein the first resin layer comprises a thermosetting resin, and
the second resin layer comprises a thermoplastic resin.

10. The printed circuit board of claim 1, wherein a ratio of a diameter of a portion of the via hole adjacent to the pad to the diameter of the portion of the via hole adjacent to the opening is greater than 0.8 and less than 1.

11. The printed circuit board of claim 3, wherein a thickness of the metal layer is greater than a thickness of the seed layer.

12. A printed circuit board comprising:
an insulating material;
a first pad disposed along a first surface of the insulating material;
a via penetrating through the insulating material and disposed on the first pad; and
a second pad disposed on the via,
wherein the second pad comprises:
a metal layer having a ring shape and disposed on a second surface of the insulating material so as not to overlap the via;
a seed layer continuously disposed along the second surface of the insulating material, an inner surface of the metal layer, and a surface of the metal layer; and
an electroplating layer disposed on the seed layer.

13. The printed circuit board of claim 12, wherein an inner diameter of the metal layer is greater than a diameter of a portion of the via adjacent to the metal layer.

14. The printed circuit board of claim 12, wherein a ratio of a thickness of the via to an inner diameter of the metal layer is greater than 0.66 and less than 0.83.

15. The printed circuit board of claim 12, wherein the insulating material comprises:
a first resin layer; and
a second resin layer stacked on the first resin layer, and comprising a material different from a material of the first resin layer.

16. The printed circuit board of claim 15, wherein the first resin layer comprises a thermosetting resin, and
the second resin layer comprises a thermoplastic resin.

17. A printed circuit board comprising:
an insulating material;
a pad disposed in the insulating material along a first surface of the insulating material;
a metal layer disposed on a second surface of the insulating material and comprising an opening that at least partially overlaps the pad in a thickness direction of the printed circuit board;
a via hole connecting the pad to the opening; and
a conductor disposed in the via hole.

18. The printed circuit board of claim 17, wherein the opening completely overlaps the pad in the thickness direction of the printed circuit board.

19. The printed circuit board of claim 18, wherein the conductor comprises a seed layer having a stepwise structure extending from the metal layer to the pad.
